(19) United States
(12) Patent Application Publication
(10) Pub. No.: US 2020/0027833 A1
(43) Pub. Date: Jan. 23, 2020

(54) Electronic Component Package

(71) Applicant: SAMSUNG ELECTRONICS CO., LTD., Suwon-si (KR)

(72) Inventors: Ji Hyun Lee, Suwon-si (KR); Jung Gon Choi, Suwon-si (KR); Kyoung Moo Harr, Suwon-si (KR)

(73) Assignee: SAMSUNG ELECTRONICS CO., LTD., Suwon-si (KR)

(21) Appl. No.: 16/293,221

(22) Filed: Mar. 5, 2019

(30) Foreign Application Priority Data
Jul. 19, 2018 (KR) 10-2018-0084232

(51) Int. Cl. H01L 23/528; H01L 23/522; H01L 23/31; H01L 23/00

(52) U.S. Cl. CPC H01L 23/5283; H01L 23/5226; H01L 23/3121; H01L 23/3171; H01L 24/17; H01L 2224/0231; H01L 2224/0401; H01L 2224/02377; H01L 2224/02379; H01L 2224/02381; H01L 2224/02373; H01L 24/09

(57) ABSTRACT

A semiconductor package includes: a semiconductor chip; an encapsulant covering at least a portion of the semiconductor chip; a connection structure disposed on an active surface of the semiconductor chip, and including one or more redistribution layers electrically connected to a connection pad of the semiconductor chip; a surface treatment layer disposed on a surface of a lowermost redistribution layer, among one or more redistribution layers, of the connection structure; and a passivation layer disposed on the connection structure, covering at least a portion of each of the lowermost redistribution layer and the surface treatment layer, and having an opening exposing at least a portion of the surface treatment layer. A surface on which the surface treatment layer is disposed, of the lowermost redistribution layer, has a surface roughness greater than that of an opposite surface, and the surface treatment layer has irregularities along the surface roughness.

### CROSS-REFERENCE TO RELATED APPLICATION

This application claims the benefit of priority to Korean Patent Application No. 10-2018-0084232, filed on Jul. 19, 2018 with the Korean Intellectual Property Office, the entirety of which is incorporated herein by reference.

### TECHNICAL FIELD

The present disclosure relates to a semiconductor package, and more particularly, to a fan-out semiconductor package in which a connection pad of a semiconductor chip may be redistributed outwardly of a fan-out region.

### BACKGROUND

A significant recent trend in the development of technology related to semiconductor chips has been reductions in the size of semiconductor chips. Therefore, in the field of package technology, in accordance with a rapid increase in demand for small-sized semiconductor chips, or the like, the implementation of a semiconductor package, having a compact size while including a plurality of pins, has been demanded.

One type of package technology suggested to satisfy the technical demand described above, is a fan-out semiconductor package. Such a fan-out semiconductor package has a compact size and may allow a plurality of pins to be implemented by redistributing connection terminals outwardly of a region in which a semiconductor chip is disposed.

On the other hand, in the case of a semiconductor package, an under-bump metallurgy (UBM) is formed in a lowermost side of the redistribution layer to connect solder balls, normally. In some specific semiconductor package products, it is required to omit an under-bump metallurgy to significantly reduce a scratch caused by an under-bump metallurgy.

### SUMMARY

An aspect of the present disclosure provides a fan-out semiconductor package capable of securing excellent interfacial adhesion and reliability while omitting an under-bump metallurgy, in a manner similar to the case in which the under-bump metallurgy is provided.

According to an aspect of the present disclosure, a roughness treatment is relatively excessively performed on a surface of a lowermost redistribution layer resulting in significant surface roughness, a surface treatment layer is formed on the surface having the surface roughness, and thus the surface treatment layer is provided to have a form of irregularities along surface roughness of a surface of a lowermost redistribution layer.

According to an aspect of the present disclosure, a semiconductor package includes: a semiconductor chip having an active surface on which a connection pad is disposed and an inactive surface opposing the active surface; an encapsulant covering at least a portion of the semiconductor chip; a connection structure disposed on the active surface of the semiconductor chip, and including one or more redistribution layers electrically connected to the connection pad; a surface treatment layer disposed on a surface of a lowermost redistribution layer, among one or more redistribution layers, of the connection structure; and a passivation layer disposed on the connection structure, covering at least a portion of each of the lowermost redistribution layer and the surface treatment layer, and having an opening exposing at least a portion of the surface treatment layer. A surface on which the surface treatment layer is disposed, of the lowermost redistribution layer, has a surface roughness greater than that of a surface of the lowermost redistribution layer opposite to the surface on which the surface treatment layer is disposed, and the surface treatment layer has irregularities along the surface roughness of the lowermost redistribution.

According to an aspect of the present disclosure, a semiconductor package includes: a semiconductor chip having an active surface on which a connection pad is disposed and an inactive surface opposing the active surface; an encapsulant covering at least a portion of the semiconductor chip; a connection structure disposed on the active surface of the semiconductor chip, and including one or more redistribution layers electrically connected to the connection pad; a surface treatment layer including a first conductor layer disposed on a surface of a lowermost redistribution layer, among the one or more redistribution layers, and a second conductor layer disposed on the first conductor layer; and a passivation layer disposed on the connection structure, covering at least a portion of each of the lowermost redistribution layer and the surface treatment layer, and having an opening exposing at least a portion of the surface treatment layer. The first conductor layer and the second conductor layer have irregularities corresponding to each other.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a block diagram schematically illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a printed circuit board and is ultimately mounted on a mainboard of an electronic device;

FIG. 6 is a schematic cross-sectional view illustrating a case in which a fan-in semiconductor package is embedded in a printed circuit board and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a fan-out semiconductor package;

FIG. 10 is a schematic plan view taken along line I-I′ of the fan-out semiconductor package of FIG. 9;

FIGS. 11A and 11B are schematic process drawings illustrating a manufacturing example of the fan-out semiconductor package of FIG. 9;

FIG. 12 is a schematic cross-sectional view illustrating another example of a fan-out semiconductor package; and

FIG. 13 is a schematic cross-sectional view illustrating another example of a fan-out semiconductor package.

### DETAILED DESCRIPTION

Hereinafter, embodiments of the present disclosure will be described as follows with reference to the attached drawings.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being ‘on,’ ‘connected to,’ or ‘coupled to’ another element, it can be directly ‘on,’ ‘connected to,’ or ‘coupled to’ the other element or other elements intervening therebetween may be present. In contrast, when an element is referred to as being ‘directly on,’ ‘directly connected to,’ or ‘directly coupled to’ another element, there may be no other elements or layers intervening therebetween. Like numerals refer to like elements throughout. As used herein, the term ‘and/or’ includes any and all combinations of one or more of the associated listed items.

It will be apparent that although the terms first, second, third, etc. may be used herein to describe various members, components, regions, layers and/or sections, any such members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as ‘above,’ upper,′ ‘below,’ and ‘lower’ and the like, may be used herein for ease of description to describe one element's relationship relative to another element(s) as shown in the figures. It will be understood that spatially relative terms are intended to encompass different orientations of the device in use or operation, in addition to the orientation depicted in the figures. For example, if the device in the figures is turned over, elements described as ‘above,’ or ‘upper’ relative to other elements would then be oriented ‘below,’ or ‘lower’ relative to the other elements or features. Thus, the term ‘above’ can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present disclosure is not limited thereby. As used herein, the singular forms ‘a,’ ‘an,’ and ‘the’ are intended to include the plural forms as well, unless the context clearly indicates otherwise. It will be further understood that the terms ‘comprises,’ and/or ‘comprising’ when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present disclosure will be described with reference to schematic views illustrating embodiments of the present disclosure. In the drawings, for example, due to manufacturing techniques and/or tolerances, modifications of the shape shown may be estimated. Thus, embodiments of the present disclosure should not be construed as being limited to the particular shapes of regions shown herein, for example, to include a change in shape results in manufacturing. The following embodiments may also be constituted alone, in combination or in partial combination.

The contents of the present disclosure described below may have a variety of configurations and propose only a required configuration herein, but are not limited thereto.

Electronic Device

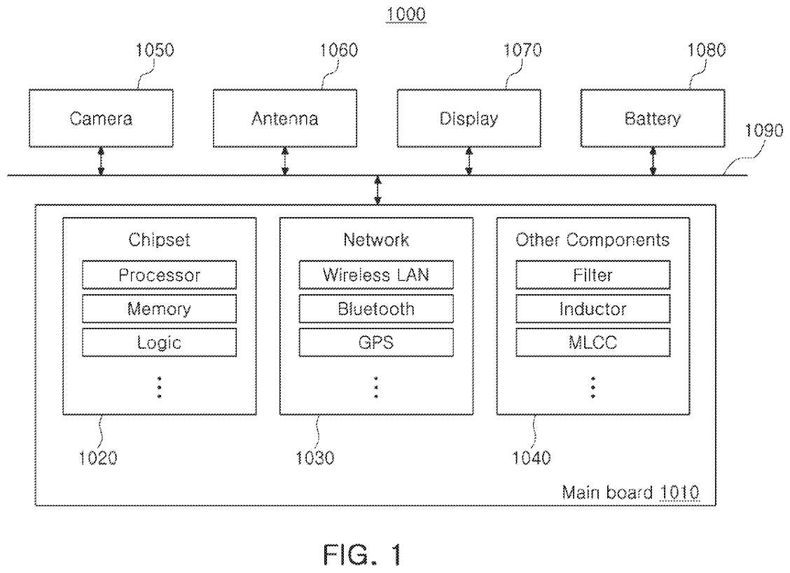

FIG. 1 is a schematic block diagram illustrating an example of an electronic device system.

Referring to FIG. 1, an electronic device 1000 may receive a motherboard 1010. The mother board 1010 may include chip related components 1020, network related components 1030, other components 1040, or the like, physically or electrically connected thereto. These components may be connected to others to be described below to form various signal lines 1090.

The chip associated components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like, or the like. However, the chip associated components 1020 are not limited thereto, and may include other types of chip associated components. In addition, the chip-associated components 1020 may be combined with each other.

The network associated components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the abovementioned protocols. However, the network associated components 1030 are not limited thereto, but may also include a variety of other wireless or wired standards or protocols. In addition, the network associated components 1030 may be combined with each other, together with the chip associated components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 includes other components that may or may not be physically or electrically connected to the mainboard 1010. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

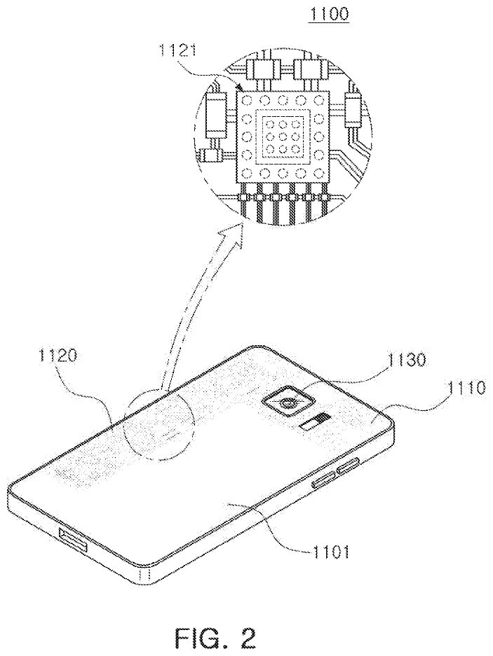

FIG. 2 is a schematic perspective view illustrating an example of an electronic device.

Referring to FIG. 2, a semiconductor package may be used for various purposes in the various electronic devices 1000 as described above. For example, a printed circuit board 1110 such as a main board may be accommodated in a body 1101 of a smartphone 1100, and various electronic components 1120 may be physically or electrically connected to the printed circuit board 1110. In addition, other components that may or may not be physically or electrically connected to the printed circuit board 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-In Semiconductor Package

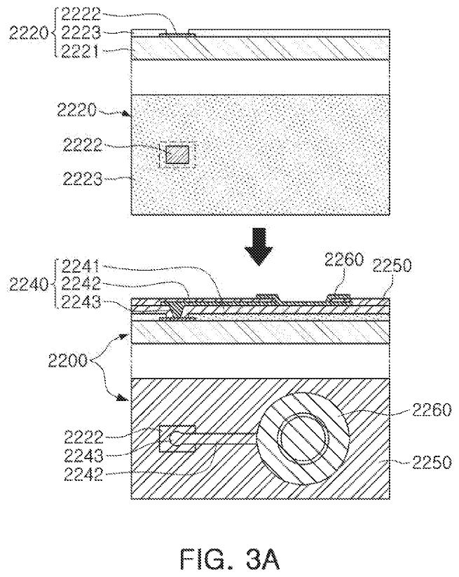

FIGS. 3A and 3B are schematic cross-sectional views illustrating states of a fan-in semiconductor package before and after being packaged.

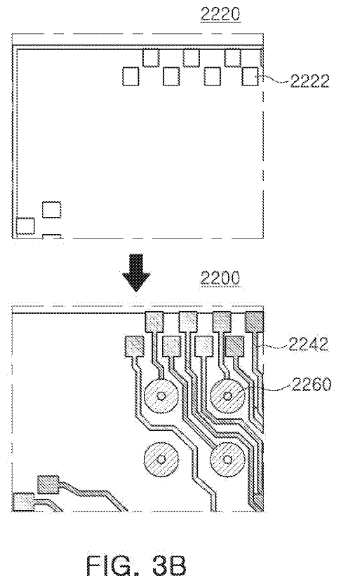

FIG. 4 is schematic cross-sectional views illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least a portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection structure 2240 may be formed depending on a size of the semiconductor chip 2220 on the semiconductor chip 2220 in order to redistribute the connection pads 2222. The connection structure 2240 may be formed by forming an insulating layer 2241 on the semiconductor chip 2220 using an insulating material such as a photoimageable dielectric (PID) resin, forming via holes 2243h opening the connection pads 2222, and then forming wiring patterns 2242 and vias 2243. Then, a passivation layer 2250 protecting the connection structure 2240 may be formed, an opening 2251 may be formed, and an under-bump metallurgy 2260, or the like, may be formed. That is, a fan-in semiconductor package 2200 including, for example, the semiconductor chip 2220, the connection structure 2240, the passivation layer 2250, and the under-bump metallurgy 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In m detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in electronic component package on the mainboard of the electronic device.

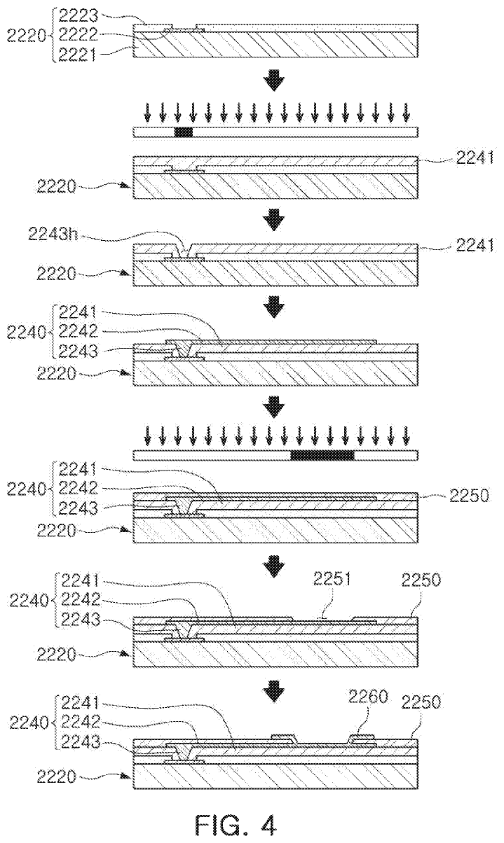

FIG. 5 is a schematic cross-sectional view illustrating a case in which a fan-in semiconductor package is mounted on a printed circuit board and is ultimately mounted on a mainboard of an electronic device.

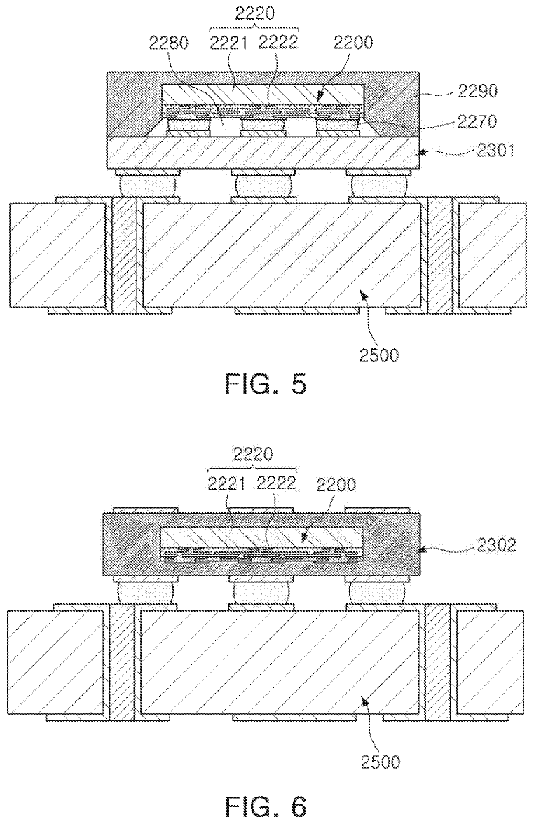

FIG. 6 is a schematic cross-sectional view illustrating a case in which a fan-in semiconductor package is embedded in a printed circuit board and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a printed circuit board 2301, and the fan-in semiconductor package 2200 may be ultimately mounted on a mainboard 2500 of an electronic device in a state in which it is mounted on the printed circuit board 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate printed circuit board 2302, connection pads 2222, that is, I/O terminals, of the semiconductor chip 2220 may be redistributed by the printed circuit board 2302 in a state in which the fan-in semiconductor package 2200 is embedded in the printed circuit board 2302, and the fan-in semiconductor package 2200 may ultimately be mounted on a mainboard 2500 of an electronic device.

As described above, it may be difficult to directly mount and use the fan-in semiconductor package on the mainboard of the electronic device. Therefore, the fan-in semiconductor package may be mounted on the separate printed circuit board and be then mounted on the mainboard of the electronic device through a packaging process or may be mounted and used on the mainboard of the electronic device in a state in which it is embedded in the printed circuit board.

Fan-Out Semiconductor Package

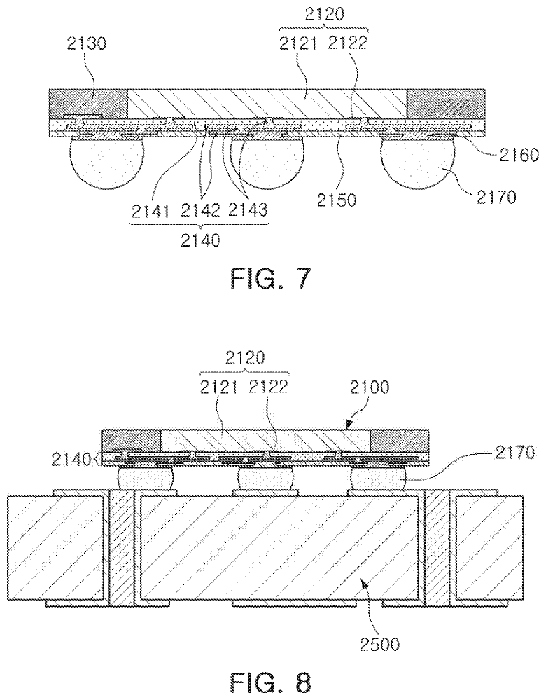

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection structure 2140. In this case, a passivation layer 2150 may further be formed on the connection structure 2140, and an under-bump metallurgy 2160 may further be formed in openings of the passivation layer 2150. Solder balls 2170 may further be formed on the under-bump metallurgy 2160. The semiconductor chip 2120 may be an integrated circuit (IC) including a body 2121, the connection pads 2122, and the like. The connection structure 2140 may include insulating layers 2141, redistribution layers 2142 formed on the insulating layer 2241, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection structure formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection structure formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate printed circuit board, as described below.

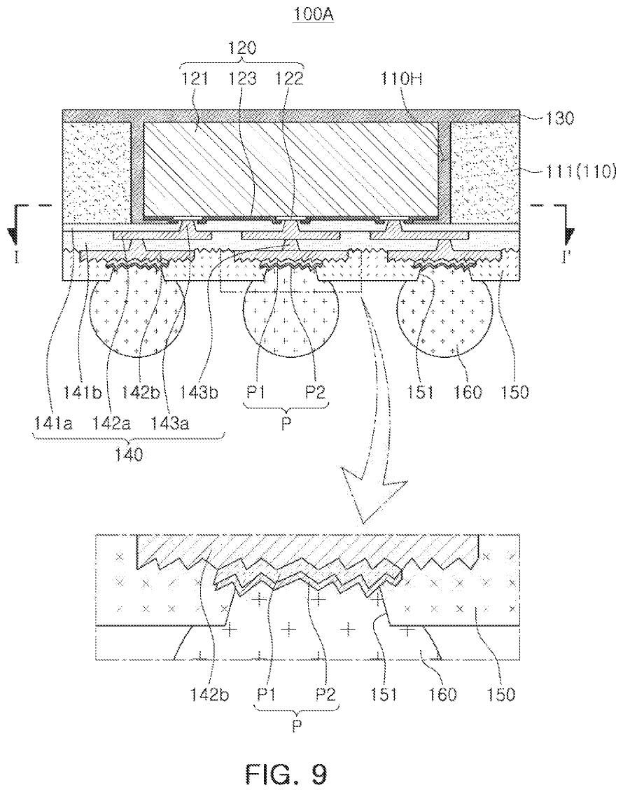

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection structure 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate printed circuit board, or the like.

As described above, since the fan-out semiconductor package may be mounted on the mainboard of the electronic device without using the separate printed circuit board, the fan-out semiconductor package may be implemented at a thickness lower than that of the fan-in semiconductor package using the printed circuit board. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a printed circuit board, or the like, having a scale, a purpose, and the like, different from those of the fan-out semiconductor package, and having the fan-in semiconductor package embedded therein.

Hereinafter, an under-bump metallurgy may be omitted. Nevertheless, in a manner similar to the case in which the under-bump metallurgy is provided, a fan-out semiconductor package capable of securing excellent interfacial adhesion and reliability will be described with reference to the drawings.

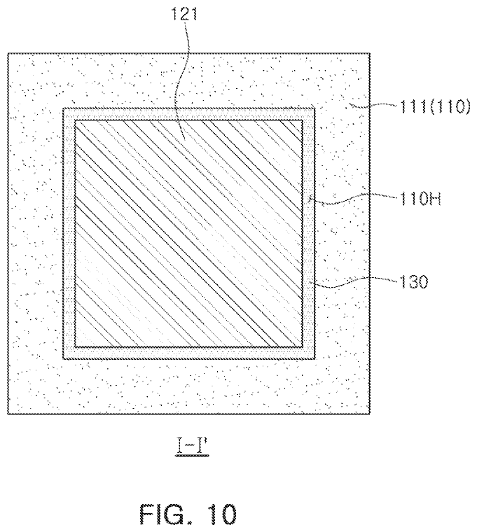

FIG. 9 is a schematic cross-sectional view illustrating an example of a fan-out semiconductor package.

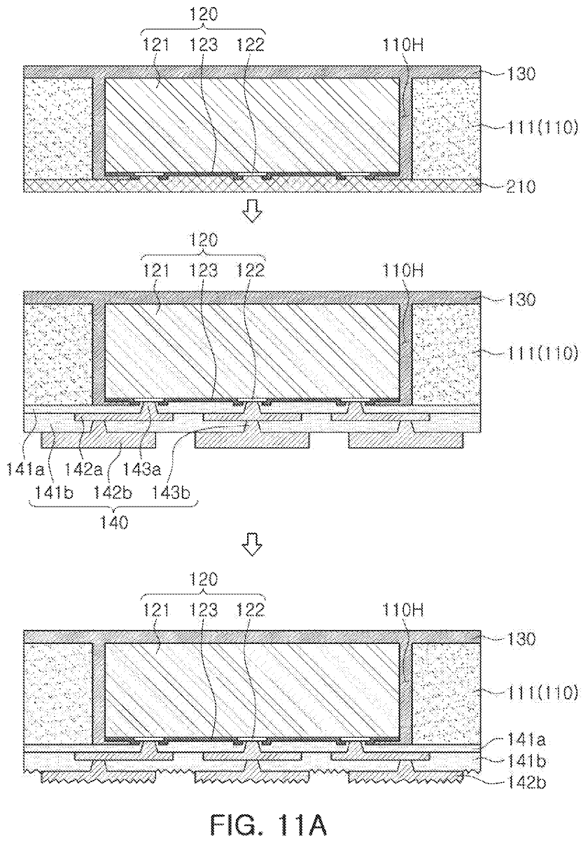

FIG. 10 is a schematic plan view taken along line I-I′ of the fan-out semiconductor package of FIG. 9.

Referring to FIG. 9, a fan-out semiconductor package 100A according to an exemplary embodiment may include a frame 110 having a through-hole 110H, a semiconductor chip 120 disposed in the through-hole 110H of the frame 110 and having an active surface on which a connection pad 122 is disposed and an inactive surface disposed opposing the active surface, an encapsulant 130 covering at least a portion of each of the frame 110 and the semiconductor chip 120 and filling at least a portion of the through-hole 110H, a connection structure 140 disposed on the frame 110 and the active surface of the semiconductor chip 120 and including redistribution layers 142a and 142b electrically connected to the connection pad 122, and a passivation layer 150 disposed on the connection structure 140 and covering at least a portion of the lowermost distribution layer 142b of the redistribution layers 142a and 142b. A lower surface, covered by the passivation layer 150, of the lowermost redistribution layer 142b may have a surface having surface roughness greater than that of an upper surface, opposite to the lower surface. In this case, on a surface of the lowermost redistribution layer 142b, a surface treatment layer P formed to have irregularities along surface roughness of the surface is disposed. The passivation layer 150 may cover at least a portion of the surface treatment layer P, and the opening 151 may expose at least a portion of the surface treatment layer P. The surface treatment layer P may include a plurality of conductor layers P1 and P2, each having irregularities.

Meanwhile, in the case of the semiconductor package, an under-bump metallurgy is formed in a lowermost side of the redistribution layer to connect solder balls, normally. In the case of a package having a strip size, during a memory stack process such as a NAND flash, a scratch may occur on a surface on which the under-bump metallurgy is formed. Thus, to significantly reduce the scratch described above, it is considered to omit the under-bump metallurgy. However, when the under-bump metallurgy is omitted, a redistribution layer of an outermost layer is to be an outermost layer connected to a solder ball. In this case, in the case of a surface treatment layer such as nickel (Ni)/gold (Au), formed on a redistribution layer of an outermost layer, interface adhesion with a passivation layer, an insulating material, is weak, resulting in reduced board level reliability.

On the other hand, in the case of the fan-out semiconductor package 100A according to an example, before a surface treatment layer P such as nickel (Ni)/gold (Au) is formed, relatively strong roughness treatment is performed on a surface of the lowermost redistribution layer 142b. Thereafter, the surface treatment layer P is formed on the treated surface of the lowermost redistribution layer 142b. Thus, the surface treatment layer P is provided to have a form with irregularities along surface roughness of the lowermost redistribution layer 142b. Due to an anchoring effect through the irregularities described above, the interface adhesion between the surface treatment layer P and the passivation layer 150 may be improved. Thus, during a test of board level reliability, a problem of delamination may be improved. Here, formation of irregularities along surface roughness is not limited to formation of irregularities having a roughness value with the same numerical value and the same shape, but indicates formation of irregularities, substantially the same or similar along a shape of surface roughness.

Meanwhile, the lowermost redistribution layer 142b may include a copper (Cu) layer, and the surface treatment layer P may include a nickel (Ni) layer, disposed on the copper (Cu) layer of the lowermost redistribution layer 142b, as a first conductor layer P1, and a gold (Au) layer, disposed on the nickel (Ni) layer, as a second conductor layer P2. In this case, the nickel (Ni) layer has irregularities along surface roughness of the copper (Cu) layer, and the gold (Au) layer has irregularities along the irregularities of the nickel (Ni) layer. For example, the surface roughness of the surface of the lowermost redistribution layer 142b, for example, the surface roughness of the copper (Cu) layer may be 1 μm to 3 μm, preferably, may exceed 1 μm and may be equal to or less than 3 μm. Thus, the surface treatment layer P, for example, each of the nickel (Ni) layer P1 and the gold (Au) layer P2 also has irregularities of 1 μm to 3 μm, preferably, exceeding 1 μm and equal to or less than 3 μm. Here, the surface roughness refers to center line average roughness Ra, and the irregularities also refer to a numerical value including, but not limited to, the center line average roughness Ra derived using a measurement method of the center line average roughness Ra in a similar manner. The measurement may be performed using a known 3D profiler.

Meanwhile, a thickness of the lowermost redistribution layer 142b, for example, a thickness of the copper (Cu) layer may be thicker than a thickness of the surface treatment layer P, for example, a thickness of each of the nickel (Ni) layer, which is the first conductor layer P1, and the gold (Au) layer, which is the second conductor layer P2. When the thickness of the copper (Cu) layer is thicker, the nickel (Ni) layer and the gold (Au) layer have irregularities along surface roughness of the copper (Cu) layer. In a similar perspective, a thickness of the nickel (Ni) layer may be thicker than a thickness of the gold (Au) layer. The thickness of the copper (Cu) layer may be 5 μm to 7 μm, the thickness of the nickel (Ni) layer may be 4 μm to 5 μm, and the thickness of the gold (Au) layer may be 0.5 μm to 1 μm.

The respective components included in the fan-out semiconductor package 100A according to the exemplary embodiment will hereinafter be described in more detail.

The frame 110 may improve rigidity of the fan-out semiconductor package 100A depending on certain materials, and serve to secure uniformity of a thickness of the encapsulant 130. When wiring layers, wiring vias, and the like, are formed in the frame 110, to be described layer, the fan-out semiconductor package 100A may be utilized as a package-on-package (POP) type package. The frame 110 may have a through-hole 110H. The semiconductor chip 120 may be disposed in the through-hole 110H to be spaced apart from the frame 110 by a predetermined distance. Side surfaces of the semiconductor chip 120 may be surrounded by the frame 110. However, such a form is only an example and may be variously modified to have other forms, and another function may be performed depending on such a form.

The frame 110 may include an insulating layer 111. For example, an insulating material may be used as the material of the insulating layer 111. In this case, the insulating material may be a material suitable for a core layer, for example, a thermosetting resin such as an epoxy resin, a thermoplastic resin such as a polyimide resin, a resin in which thermosetting resin or thermoplastic resin is mixed with an inorganic filler or is impregnated together with an inorganic filler in a core material such as a glass fiber (or a glass cloth or a glass fabric), in detail, prepreg, but is not limited thereto.

The semiconductor chip 120 may be an integrated circuit (IC) provided in an amount of several hundred to several million or more elements integrated in a single chip. In this case, the IC may be, for example, a processor chip such as a central processor (for example, a central processing unit (CPU)), a graphics processor (for example, a graphics processing unit (GPU)), a field programmable gate array (FPGA), a digital signal processor, a cryptographic processor, a microprocessor, a microcontroller, or the like, in detail, an application processor (AP). However, the semiconductor chip may be a logic chip such as an analog-to-digital converter (ADC), an application-specific integrated circuit (ASIC), or the like, or a memory chip such as a volatile memory (for example, a dynamic random access memory (DRAM)), a non-volatile memory (for example, a read only memory (ROM)), a memory chip such as a flash memory, a power management IC (PMIC), or the like, but is not limited thereto. Moreover, these chip related components are also combined.

The semiconductor chip 120 may be formed on the basis of an active wafer. In this case, a base material of a body 121 of the semiconductor chip 120 may be silicon (Si), germanium (Ge), gallium arsenide (GaAs), or the like. Various circuits may be formed on the body 121. The connection pads 122 may electrically connect the semiconductor chip 120 to other components. A material of each of the connection pads 122 may be a conductive material such as aluminum (Al), or the like. A passivation layer 123 exposing the connection pads 122 may be formed on the body 121, and may be an oxide layer, a nitride layer, or the like, or a double layer of an oxide layer and a nitride layer. A lower surface of the connection pad 122 may have a step with respect to a lower surface of the encapsulant 130 through the passivation layer 123. Thus, the encapsulant 130 may be prevented from bleeding to the lower surface of the connection pad 122. An insulating layer (not illustrated), and the like, may also be further disposed in other required positions. The semiconductor chip 120 may be a bare die, but if necessary, a redistribution layer (not shown) may further be formed on the active surface of the semiconductor chip 120, or the semiconductor chip 120 may be a packaged type, in which bumps (not shown), or the like, are connected to the connection pads 122.

The encapsulant 130 may protect the frame 110, the semiconductor chip 120, and the like. An encapsulation form of the encapsulant 130 is not particularly limited, but may be a form in which the encapsulant 130 surrounds at least a portions of the frame 110, the semiconductor chip 120, and the like. In this case, the encapsulant 130 may cover the frame 110 and the inactive surface of the semiconductor chip 120, and fill a space between a wall surface of the through-hole 110H and a side surface of the semiconductor chip 120. Moreover, the encapsulant 130 may fill at least a portion of a space between the passivation film 123 of the semiconductor chip 120 and the connection structure 140. Meanwhile, the encapsulant 130 may fill the through-hole 110H to thus serve as an adhesive and reduce buckling of the semiconductor chip 120 depending on certain materials.

A material of the encapsulant 130 is not particularly limited. For example, an insulating material may be used as the material of the encapsulant. In this case, the insulating material may be a thermosetting resin such as an epoxy resin, a thermoplastic resin such as a polyimide resin, a resin in which thermosetting resin or thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, an encapsulant formed of a photoimageable material, that is, a photoimageable encapsulant (PIE) may also be used.

The connection structure 140 may redistribute the connection pads 122 of the semiconductor chip 120. Several tens to several hundreds of connection pads 122 of the semiconductor chip 120 having various functions may be redistributed by the connection structure 140, and may be physically or electrically externally connected through the electrical connection structures 160 depending on functions. The connection structure 140 may include insulating layers 141a and 141b, redistribution layers 142a and 142b disposed on the insulating layers 141a and 141b, and connection vias 143a and 143b passing through the insulating layers 141a and 141b and connected to the redistribution layers 142a and 142b. Each of the insulating layers 141a and 141b, the redistribution layers 142a and 142b, and the connection vias 143a and 143b may be configured in a greater number than that illustrated in the drawings, or may only include a single layer.

A material of the insulating layers 141a and 141b may be an insulating material. The insulating material may be a photosensitive insulating material such as a photoimageable dielectric (PID) material in addition to the abovementioned insulating material. In this case, the insulating layers 141a and 141b are formed to have a smaller thickness, and a fine pitch of the connection vias 143a and 143b may be achieved more easily. The materials of the insulating layers 141a and 141b may be the same as each other, and may also be different from each other.

The redistribution layers 142a and 142b may substantially serve to redistribute the connection pads 122, and a formation material thereof may be a conductive material such as copper (Cu), aluminum (Al), silver (Ag), tin (Sn), gold (Au), nickel (Ni), lead (Pb), titanium (Ti), or alloys thereof. The redistribution layers 142a and 142b may perform various functions depending on designs of corresponding layers. For example, the redistribution layer may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layer may include via pads, electrical connection structure pads, and the like.

The surface treatment layer P is disposed on a surface of the lowermost redistribution layer 142b. The surface treatment layer P may include a plurality of conductor layers P1 and P2. The lowermost redistribution layer 142b may include a copper (Cu) layer according to the related art, and each of the conductor layers P1 and P2 may be a nickel (Ni) layer and a gold (Au) layer, but is not limited thereto. A surface of the lowermost redistribution layer 142b may have surface roughness, greater than that of an opposite surface, by relatively strong roughness treatment. For example, the surface of the lowermost redistribution layer may have surface roughness of 1 μm to 3 μm, preferably, exceeding 1 μm and equal to or less than 3 μm. Each of the conductor layers P1 and P2 of the surface treatment layer P, formed on the surface having relatively great surface roughness as described above, may be formed to have irregularities of 1 μm to 3 μm, preferably, exceeding 1 μm and equal to or less than 3 μm, along surface roughness, byway of example. As described above, the surface treatment layer P, in contact with the passivation layer 150, in detail, the second conductor layer P2 may have irregularities. As described above, interface adhesion may be improved, resulting in improved board level reliability.

Meanwhile, if surface roughness of a lowermost redistribution layer 142b, for example, a copper (Cu) layer, is less than 1 μm, it may be difficult that the surface treatment layer P has significant irregularities. If the surface roughness of the lowermost redistribution layer 142b exceeds 3 μm, it may be difficult for the surface treatment layer P, for example, the nickel (Ni) layer and the gold (Au) layer to grow. In a similar manner, if the first conductor layer P1, for example, the nickel (Ni) layer, has irregularities less than 1 μm, it may be difficult that the second conductor layer P2 has significant irregularities. If the nickel (Ni) layer has irregularities exceeding 3 μm, there may be a problem in growth of the second conductor layer P2, for example, the gold (Au) layer. Moreover, if the second conductor layer P2, for example, the gold (Au) layer, has irregularities less than 1 μm, it may be difficult to improve adhesion. In addition, irregularities of the first conductor layer P1, for example, the nickel (Ni) layer, are preferably equal to or less than 3 μm. In this case, it may be difficult that the second conductor layer P2, for example, the gold (Au) layer, has irregularities exceeding 3 μm.

Meanwhile, a thickness of the lowermost redistribution layer 142b, for example, a thickness of the copper (Cu) layer may be thicker than a thickness of the surface treatment layer P, for example, a thickness of each of the nickel (Ni) layer, which is the first conductor layer P1, and the gold (Au) layer, which is the second conductor layer P2. When the thickness of the copper (Cu) layer is thicker, the nickel (Ni) layer and the gold (Au) layer have irregularities along surface roughness of the copper (Cu) layer. Similarly, a thickness of the nickel (Ni) layer may be thicker than a thickness of the gold (Au) layer. The thickness of the copper (Cu) layer may be 5 μm to 7 μm, the thickness of the nickel (Ni) layer may be 3 μm to 5 μm, and the thickness of the gold (Au) layer may be 0.5 μm to 1 μm. When the range described above is satisfied, significant irregularities may be realized, and thus adhesion may be easily improved.

On the other hand, the lowermost redistribution layer 142b, on which the surface treatment layer P is formed as described above, may be a pad for connection with the electrical connection structure 160, which will be described later. In other words, the surface treatment layer P, described above, may be formed on a plurality of electrical connection structure pads.

The connection vias 143a and 143b may electrically connect the redistribution layers 142a and 142b, and the connection pads 122, and the like, formed on different layers, to each other, resulting in an electrical path in the fan-out semiconductor package 100A. A material of each of the connection vias 143a and 143b may be a conductive material such as copper (Cu), aluminum (Al), silver (Ag), tin (Sn), gold (Au), nickel (Ni), lead (Pb), titanium (Ti), or alloys thereof. The connection vias 143a and 143b may be a filled type or a conformal type, or may have a tapered shape.

The passivation layer 150 may be provided on the connection structure 140. The passivation layer 150 may protect the connection structure 140 from external physical or chemical damage. The passivation layer 150 may have openings 151 exposing at least a portions of the surface treatment layer P, formed on a surface of the lowermost redistribution layer 142b of the connection structure 140. The number of openings 151 formed in the passivation layer 150 may be several tens to several thousands. A material of the passivation layer 150 is not particularly limited. For example, an insulating material may be used as the material of the passivation layer. In this case, the insulating material may be a thermosetting resin such as an epoxy resin, a thermoplastic resin such as a polyimide resin, a resin in which thermosetting resin or thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used.

The electrical connection structure 160 connected to the surface treatment layer P, having been exposed, may be disposed on in the opening 151 of the passivation layer 150. The surface treatment layer P has irregularities as described above, and thus irregularities may also be provided in a bonding interface with the electrical connection structure 160. Thus, connection reliability may be excellent, resulting in further improved board level reliability. The electrical connection structures 160 may physically or electrically externally connect the fan-out semiconductor package 100A. For example, the fan-out semiconductor package 100A may be mounted on the mainboard of the electronic device through the electrical connection structures 160. The electrical connection structure 160 may be formed of a low melting point metal, such as, tin (Sn) or an alloy including tin (Sn). In more detail, the electrical connection structure 160 may be formed of a solder, or the like. However, this is only an example, and a material of the electrical connection structure is not particularly limited thereto. Each of the electrical connection structures 160 may be a land, a ball, a pin, or the like. The electrical connection structures 160 may be formed as a multilayer or single layer structure. When the electrical connection structure includes the plurality of layers, the electrical connection structure includes a copper pillar and a solder. When the electrical connection structure includes the single layer, the electrical connection structure includes a tin-silver solder or copper. However, the electrical connection structure is only an example, and the present disclosure is not limited thereto.

The number, an interval, a disposition form, and the like, of electrical connection structures 160 are not particularly limited, but may be sufficiently modified depending on design particulars by those skilled in the art. For example, the electrical connection structures 160 may be provided in an amount of several tens to several thousands according to the number of connection pads 122, or may be provided in an amount of several tens to several thousands or more or several tens to several thousands or less. At least one of the electrical connection structures 160 may be disposed in a fan-out region. The fan-out region refers to a region except for a region in which the semiconductor chip 120 is disposed. The fan-out package may have excellent reliability as compared to a fan-in package, may allow a plurality of input/output (I/O) terminals to be implemented, and may facilitate a 3D interconnection. In addition, as compared to a ball grid array (BGA) package, a land grid array (LGA) package, or the like, the fan-out package may be manufactured to have a small thickness, and may have price competitiveness.

Meanwhile, although not illustrated in the drawings, a metal thin film may be formed on the wall surface of the through-hole 110H for the purpose of radiating heat and/or shielding electromagnetic waves, if necessary. Moreover, a plurality of semiconductor chips 120 performing functions that are the same as or different from each other may be disposed in the through-hole 110H, if necessary. In addition, a separate passive component such as an inductor, a capacitor, or the like, may be disposed in the through-hole 110H, if necessary. Moreover, if necessary, a plurality of through-holes 110H may be provided, and the semiconductor chip 120 and/or a passive component may be disposed in each of the plurality of the through-holes. Moreover, if necessary, a passive component, such as a surface mount (SMT) component including, for example, an inductor, a capacitor, and the like, may be disposed on a surface of the passivation layer 150.

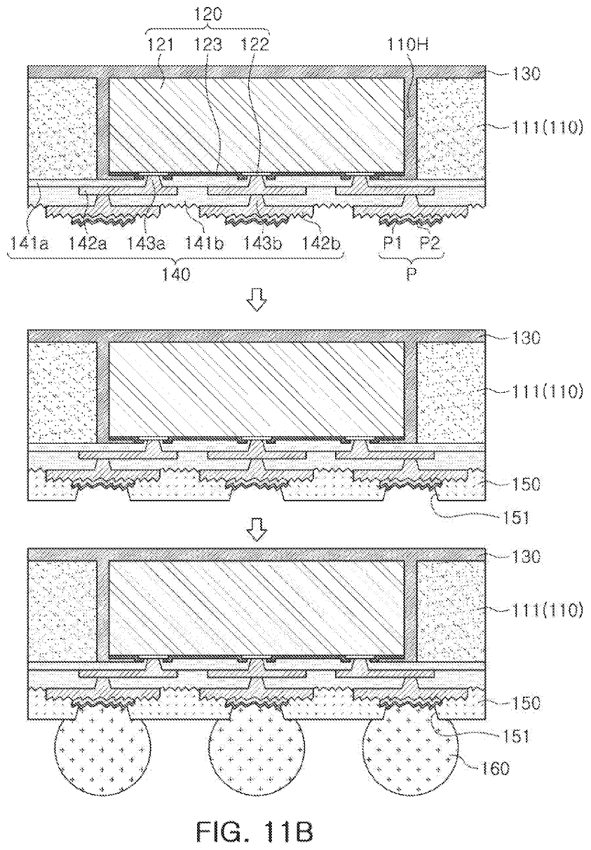

FIGS. 11A and 11B are schematic process drawings illustrating a manufacturing example of the fan-out semiconductor package of FIG. 9.

Referring to FIG. 11A, a through-hole 110H is formed in a frame 110 first, the frame 110 is attached to a tape 210, a semiconductor chip 120 in a face-down form is disposed in the through-hole 110H and is then attached to the tape 210, and the frame 110 and the semiconductor chip 120 are encapsulated by an encapsulant 130. Then, the tape 210 is removed, and a connection structure 140, including the insulating layers 141a and 141b, the redistribution layers 142a and 142b, as well as the connection vias 143a and 143b, may be formed in a region from which the tape 210 is removed. On the other hand, when a connection structure 140 includes a greater number of layers as compared with that illustrated in the drawings, a process may be performed while a carrier film (not shown) is attached on the encapsulant 130 to control warpage. Then, surface roughness may be formed using excessive roughness treatment on a lower surface of the lowermost redistribution layer 142b. At this, the surface roughness may be also formed on a lower surface of a lowermost insulating layer 141b of the connection structure 140. The roughness treatment may be chemical treatment using an etching chemical, other physical treatment, or the like, and the method is not particularly limited.

Referring to FIG. 11B, then, a surface treatment layer P is formed on a lower surface of the lowermost redistribution layer 142b, in which surface roughness is formed. The surface treatment layer P may be formed using electroless nickel plating/replacement gold plating, or the like. The surface treatment layer P, having been formed, may include a plurality of conductor layers P1 and P2, and the conductor layers P1 and P2 may be sequentially a nickel (Ni) layer and a gold (Au) layer and may have irregularities along surface roughness of a lower surface of the lowermost redistribution layer 142b. Since the surface treatment layer P is relatively thin and no planarization process is performed to the surface treatment layer P, the surface roughness of the lower surface of the lowermost redistribution layer 142b may be transferred to surfaces of the surface treatment layer P. A degree of the surface roughness of the lower surface of the surface treatment layer P may be less than, or equal to, that of the surface roughness of the lower surface of the lowermost redistribution layer 142b. The present disclosure is not limited thereto. For example, a degree of the surface roughness of the lower surface of the surface treatment layer P may be greater than that of the surface roughness of the lower surface of the lowermost redistribution layer 142b. Then, a passivation layer 150, covering the lowermost redistribution layer 142b and the surface treatment layer P, may be formed on the connection structure 140. The passivation layer 150 may be formed using a method of laminating and curing ABF, or the like. In this case, the surface treatment layer P has irregularities, and thus may have excellent interface adhesion with the passivation layer 150. Then, a plurality of openings 151, exposing at least a portion of the surface treatment layer P, are formed in the passivation layer 150, and an electrical connection structure 160, connected to the surface treatment layer P, is formed in each of the openings 151. Through a series of processes, a fan-out semiconductor package 100A according to an example may be manufactured.

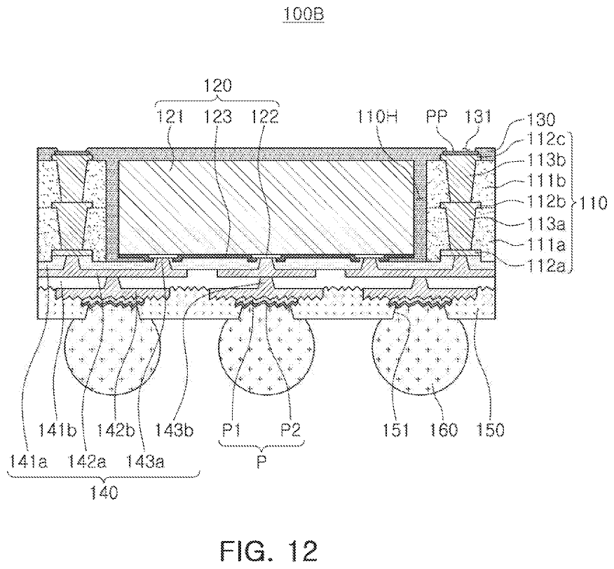

FIG. 12 is a schematic cross-sectional view illustrating another example of a fan-out semiconductor package.

Referring to FIG. 12, in a fan-out semiconductor package 100B according to another example, a frame 110 may include a first insulating layer 111a, a first wiring layer 112a embedded in the first insulating layer 111a to expose a lower surface, a second wiring layer 112b disposed on an upper surface of the first insulating layer 111a, a second insulating layer 111b disposed on an upper surface of the first insulating layer 111a and covering the second wiring layer 112b, and a third wiring layer 112c disposed on an upper surface of the second insulating layer 111b. The first to third wiring layers 112a, 112b, and 112c are electrically connected to the connection pad 122. The first wiring layer 112a and the second wiring layer 112b, as well as the second wiring layer 112b and the third wiring layer 112c may be electrically connected to each other through the first wiring via 113a and the second wiring via 113b, passing through the first insulating layer 111a and the second insulating layer 111b, respectively.

When the first wiring layer 112a is embedded in the first insulating layer 111a, a step generated due to a thickness of the first wiring layer 112a may be significantly reduced, and an insulating distance of the connection structure 140 may thus become constant. In other words, a difference between a distance from an uppermost redistribution layer 142a of the connection structure 140 to a lower surface of the first insulating layer 111a, and a distance from the uppermost redistribution layer 142a of the connection structure 140 to the connection pad 122 of the semiconductor chip 120, may be less than a thickness of the first wiring layer 112a. Thus, high-density wiring design of the connection structure 140 may be easily performed.

The first wiring layer 112a may be recessed inwardly of the first insulating layer 111a. As described above, when the first wiring layer 112a is recessed inwardly of the first insulating layer and a step is provided between a lower surface of the first insulating layer 111a and a lower surface of the first wiring layer 112a, the first wiring layer 112a may be prevented from being contaminated by bleeding of a formation material of the encapsulant 130. The second wiring layer 112b of the frame 110 may be disposed on a level between an active surface and an inactive surface of the semiconductor chip 120. The frame 110 may be formed to have a thickness corresponding to a thickness of the semiconductor chip 120, and thus the second wiring layer 112b, formed in the frame 110, may be disposed at a level between an active surface and an inactive surface of the semiconductor chip 120.

A thickness of each of the wiring layers 112a, 112b, and 112c of the frame 110 may be greater than that of each of the redistribution layers 142a and 142b of the connection structure 140. The frame 110 may have a thickness larger than that of the semiconductor chip 120, so the wiring layers 112a, 112b, and 112c may also be formed in a larger size to match the scale thereof. On the other hand, the redistribution layers 142a and 142b of the connection structure 140 may be formed in a relatively smaller size than that of the wiring layers 112a, 112b, and 112c for thinning.

A material of each of the insulating layers 111a and 111b is not particularly limited. For example, an insulating material may be used as the material of the insulating layer. In this case, the insulating material may be a thermosetting resin such as an epoxy resin, a thermoplastic resin such as a polyimide resin, a resin in which thermosetting resin or thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a PID resin may also be used as the insulating material.

The wiring layers 112a, 112b, and 112c may serve to redistribute the connection pads 122 of the semiconductor chip 120. A material of each of the wiring layers 112a, 112b, and 112c may be a conductive material such as copper (Cu), aluminum (Al), silver (Ag), tin (Sn), gold (Au), nickel (Ni), lead (Pb), titanium (Ti), or alloys thereof. The wiring layers 112a, 112b, and 112c may perform various functions depending on designs of corresponding layers. For example, the wiring layer may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers may include wiring via pads, wire pads, electrical connection structure pads, and the like.

The wiring vias 113a and 113b may electrically connect the wiring layers 112a, 112b, and 112c formed on different layers to each other, resulting in an electrical path in the frame 110. A material of each of the wiring vias 113a and 113b may be a conductive material. Each of the wiring vias 113a and 113b may be completely filled with the conductive material, or the conductive material may also be formed along a wall surface of each of wiring via holes. Each of the wiring vias may have all of the shapes known in the related art, such as a tapered shape, a cylindrical shape, and the like.

When a hole for the first wiring via 113a is formed, some pads of the first wiring layer 112a may serve as a stopper. In this regard, it may be advantageous in a process in that the first wiring via 113a has a tapered shape in which a width of an upper surface is greater than a width of a lower surface. In this case, the first wiring via 113a may be integrated with a pad pattern of the second wiring layer 112b. When a hole for the second wiring via 113b is formed, some pads of the second wiring layer 112b may serve as a stopper. In this regard, it may be advantageous in a process in that the second wiring via 113b has a tapered shape in which a width of an upper surface is greater than a width of a lower surface. In this case, the second wiring via 113b may be integrated with a pad pattern of the third wiring layer 112c.

The surface treatment layer PP may be disposed on the third wiring layer 112c, and the surface treatment layer PP may be exposed by the opening 131, passing through the encapsulant 130. The surface treatment layer PP may be a multilayer of nickel (Ni)/gold (Au), but is not limited thereto.

Other components, for example, those described with reference to FIGS. 9 to 11, may also be applied to the fan-out semiconductor package 100B according to another example, and a detailed description is substantially the same as that described in the fan-out semiconductor package 100A described above, and the detailed description will be omitted.

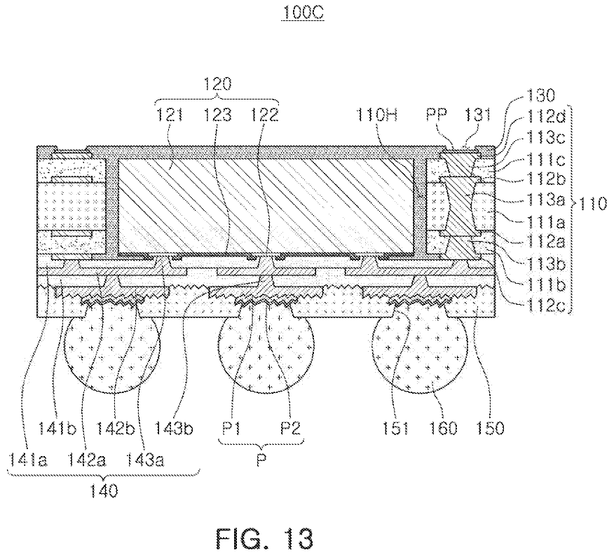

FIG. 13 is a schematic cross-sectional view illustrating another example of a fan-out semiconductor package.

Referring to FIG. 13, in a fan-out semiconductor package 100C according to another example, a frame 110 may include a first insulating layer 111a, a first wiring layer 112a and a second wiring layer 112b disposed on both sides of the first insulating layer 111a, respectively, a second insulating layer 111b disposed on a lower surface of the first insulating layer 111a and covering the first wiring layer 112a, a third redistribution layer 111c disposed on a lower surface of the second insulating layer 111b, a third insulating layer 111c disposed on an upper surface of the first insulating layer 111a and covering the second wiring layer 112b, and a fourth wiring layer 112d disposed on an upper surface of the third insulating layer 111c. The first to fourth wiring layers 112a, 112b, 112c, and 112d may be electrically connected to connection pads 122. Since the frame 110 may include a further large number of wiring layers 112a, 112b, 112c, and 112d, a connection structure 140 may be further simplified. Therefore, a decrease in a yield depending on a defect occurring in a process of forming the connection structure 140 may be suppressed. Meanwhile, the first to fourth wiring layers 112a, 112b, 112c, and 112d may be electrically connected to each other through first to third wiring vias 113a, 113b, and 113c passing through the first to third insulating layers 111a, 111b, and 111c, respectively.

The first insulating layer 111a may have a thickness greater than those of the second insulating layer 111b and the third insulating layer 111c. The first insulating layer 111a may be basically relatively thick in order to maintain rigidity, and the second insulating layer 111b and the third insulating layer 111c may be introduced in order to form a larger number of wiring layers 112c and 112d. The first insulating layer 111a may include an insulating material different from those of the second insulating layer 111b and the third insulating layer 111c. For example, the first insulating layer 111a may be, for example, prepreg including a core material, a filler, and an insulating resin, and the second insulating layer 111b and the third insulating layer 111c may be an ABF film or a PID film including a filler and an insulating resin. However, the materials of the first insulating layer 111a and the second and third insulating layers 111b and 111c are not limited thereto. Similarly, the first wiring via 113a passing through the first insulating layer 111a may have a diameter greater than those of the second and third wiring vias 113b and 113c passing through the second and third insulating layers 111b and 111c, respectively.

A lower surface of the third wiring layer 112c of the frame 110 may be disposed on a level below a lower surface of the connection pad 122 of a semiconductor chip 120. In addition, a distance between a first redistribution layer 142a of the connection structure 140 and the third wiring layer 112c of the frame 110 may be smaller than that between the first redistribution layer 142a of the connection structure 140 and the connection pad 122 of the semiconductor chip 120. The reason is that the third wiring layer 112c may be disposed on the second insulating layer 111b in a protruding form, resulting in being in contact with the connection structure 140. The first wiring layer 112a and the second wiring layer 112b of the frame 110 may be disposed on a level between an active surface and an inactive surface of the semiconductor chip 120. The frame 110 may be formed to have a thickness corresponding to a thickness of the semiconductor chip 120, and thus the first wiring layer 112a and the second wiring layer 112b, formed in the frame 110, may be disposed at a level between an active surface and an inactive surface of the semiconductor chip 120.

A thickness of each of the wiring layers 112a, 112b, 112c, and 112d of the frame 110 may be greater than that of each of the redistribution layers 142a and 142b of the connection structure 140. The frame 110 may have a thickness larger than that of the semiconductor chip 120, so the wiring layers 112a, 112b, 112c, and 112d may also be formed in a larger size. On the other hand, the redistribution layers 142a and 142b of the connection structure 140 may be formed in a relatively smaller size for thinning.

The surface treatment layer PP may be disposed on the fourth wiring layer 112d, and the surface treatment layer PP may be exposed by the opening 131, passing through the encapsulant 130. The surface treatment layer PP may be a multilayer of nickel (Ni)/gold (Au), but is not limited thereto.

Other components, for example, those described with reference to FIGS. 9 to 12, may also be applied to the fan-out semiconductor package 100C according to another example, and a detailed description is substantially the same as that described in the fan-out semiconductor package 100A described above, and the detailed description will be omitted.

As set forth above, according to an exemplary embodiment, an under-bump metallurgy is omitted, but a fan-out semiconductor package capable of securing excellent interfacial adhesion and reliability may be provided, in a manner similar to the case in which the under-bump metallurgy is provided.

While exemplary embodiments have been shown and described above, it will be apparent to those skilled in the art that modifications and variations could be made without departing from the scope of the present invention as defined by the appended claims.

What is claimed is:

1. A semiconductor package, comprising:
a semiconductor chip having an active surface on which a connection pad is disposed and an inactive surface opposing the active surface;
an encapsulant covering at least a portion of the semiconductor chip;
a connection structure disposed on the active surface of the semiconductor chip, and including one or more redistribution layers electrically connected to the connection pad;
a surface treatment layer disposed on a surface of a lowermost redistribution layer, among the one or more redistribution layers, of the connection structure; and
a passivation layer disposed on the connection structure, covering at least a portion of each of the lowermost redistribution layer and the surface treatment layer, and having an opening exposing at least a portion of the surface treatment layer,
wherein a surface on which the surface treatment layer is disposed, of the lowermost redistribution layer, has a surface roughness greater than that of a surface of the lowermost redistribution layer opposite to the surface on which the surface treatment layer is disposed, and
the surface treatment layer has irregularities along the surface roughness of the lowermost redistribution layer.

2. The semiconductor package of claim 1, wherein the surface treatment layer has a plurality of conductor layers, and
each of the conductor layers has irregularities along the surface roughness of the lowermost redistribution layer.

3. The semiconductor package of claim 2, wherein the surface on which the surface treatment layer is disposed, of the lowermost redistribution layer, has the surface roughness of 1 μm to 3 μm.

4. The semiconductor package of claim 2, wherein each of the conductor layers has irregularities of 1 μm to 3 μm.

5. The semiconductor package of claim 1, wherein the lowermost redistribution layer includes a copper (Cu) layer, and
the surface treatment layer includes a nickel (Ni) layer disposed on the copper (Cu) layer of the lowermost redistribution layer and a gold (Au) layer disposed on the nickel (Ni) layer.

6. The semiconductor package of claim 5, wherein a surface of the copper (Cu) layer has the surface roughness,
the nickel (Ni) layer has irregularities along the surface roughness of the copper (Cu) layer, and
the gold (Au) layer has irregularities along the irregularities of the nickel (Ni) layer.

7. The semiconductor package of claim 5, wherein the copper (Cu) layer is thicker than the nickel (Ni) layer and the gold (Au) layer.

8. The semiconductor package of claim 7, wherein the nickel (Ni) layer is thicker than the gold (Au) layer.

9. The semiconductor package of claim 1, further comprising: an electrical connection structure disposed on the opening of the passivation layer, and connected to the surface treatment layer, which is exposed by the opening of the passivation layer.

10. The semiconductor package of claim 9, wherein the electrical connection structure is a solder ball.

11. The semiconductor package of claim 9, wherein the surface treatment layer is disposed directly between the electrical connection structure and the lowermost redistribution layer.

12. The semiconductor package of claim 1, further comprising: a frame having a through-hole,
wherein the semiconductor chip is disposed in the through-hole, and
the encapsulant fills at least a portion of the through-hole.

13. The semiconductor package of claim 12, wherein the frame includes a first insulating layer, a first wiring layer embedded in the first insulating layer to expose a lower surface, a second wiring layer disposed on an upper surface of the first insulating layer, a first wiring via passing through the first insulating layer and electrically connecting the first wiring layer to the second wiring layer, a second insulating layer disposed on the upper surface of the first insulating layer and covering at least a portion of the second wiring layer, a third wiring layer disposed on an upper surface of the second insulating layer, and a second wiring via passing through the second insulating layer and electrically connecting the second wiring layer to the third wiring layer, and
the first to third wiring layers are electrically connected to the connection pad.

14. The semiconductor package of claim 12, wherein the frame includes a first insulating layer, a first wiring layer disposed on a lower surface of the first insulating layer, a second wiring layer disposed on an upper surface of the first insulating layer, a first wiring via passing through the first insulating layer and passing through the first insulating layer and the second insulating layer, a second insulating layer disposed on the lower surface of the first insulating layer and covering at least a portion of the first wiring layer, a third wiring layer disposed on a lower surface of the second insulating layer, a second wiring via passing through the second insulating layer and electrically connecting the first wiring layer to the third wiring layer, a third insulating layer disposed on the upper surface of the first insulating layer and covering at least a portion of the second wiring layer, a fourth wiring layer disposed on an upper surface of the third insulating layer, and a third wiring via passing through the third insulating layer and electrically connecting the second wiring layer to the fourth wiring layer, and
the first to fourth wiring layers are electrically connected to the connection pad.

15. A semiconductor package, comprising:
a semiconductor chip having an active surface on which a connection pad is disposed and an inactive surface opposing the active surface;
an encapsulant covering at least a portion of the semiconductor chip;
a connection structure disposed on the active surface of the semiconductor chip, and including one or more redistribution layers electrically connected to the connection pad;
a surface treatment layer including a first conductor layer disposed on a surface of a lowermost redistribution layer, among the one or more redistribution layers, and a second conductor layer disposed on the first conductor layer; and
a passivation layer disposed on the connection structure, covering at least a portion of each of the lowermost redistribution layer and the surface treatment layer, and having an opening exposing at least a portion of the surface treatment layer,
wherein the first conductor layer and the second conductor layer have irregularities corresponding to each other.

16. The semiconductor package of claim 15, further comprising: an electrical connection structure disposed on the opening of the passivation layer, being in contact with the passivation layer through a sidewall of the opening, and connected to the surface treatment layer, which is exposed by the opening of the passivation layer.

17. The semiconductor package of claim 16, wherein the surface treatment layer is disposed directly between the electrical connection structure and the lowermost redistribution layer.
